(19) United States
(12) Patent Application Publication
(10) Pub. No.: US 2012/0031460 A1
(43) Pub. Date: Feb. 9, 2012

(54) SOLAR BATTERY AND PRODUCTION METHOD THEREOF

(75) Inventors: Yoichi Hosoya, Ashigarakami-gun (JP); Nori Miyagishima, Ashigarakami-gun (JP); Kenji Naoi, Ashigarakami-gun (JP); Teruhiko Kuramachi, Ashigarakami-gun (JP); Ryoji Nishimura, Ashigarakami-gun (JP)

(73) Assignee: FUJIFILM CORPORATION, Minato-ku, Tokyo (JP)

(21) Appl. No.: 13/264,669

(22) PCT Filed: Apr. 8, 2010
(86) PCT No.: PCT/JP2010/056723

§ 371 Date: Oct. 14, 2011

(30) Foreign Application Priority Data
Apr. 17, 2009 (JP) 2009-101195

(51) Int. Cl. H01L 31/05; H01L 31/18; B82Y 99/00

(52) U.S. Cl. 136/244; 438/73; 977/948; 257/E31.124

(57) ABSTRACT

A solar battery including a transparent conductive film; and a solar battery element, wherein the transparent conductive film is bonded to a surface of the solar battery element, and the transparent conductive film is electrically connected to the solar battery element.

### TECHNICAL FIELD

The present invention relates to a solar battery containing at least a solar battery element to whose surface a transparent conductive film is bonded, and a method for producing the solar battery.

### BACKGROUND ART

For example, a crystalline silicon solar battery is formed in such a manner that electrodes formed of silver or aluminum are formed in a pattern on a front surface and a back surface of a silicon substrate in which a p-n junction is formed, and the electrodes are connected in series via a string of copper, or the like, so-called an interconnector, to thereby form a solar battery, which is called as a module.

The series connection by means of an interconnector is formed in such a manner that a solar battery element, in which electrodes are patterned on a silicon substrate in which a p-n junction is formed, is immersed in flux containing an activator, dried with warm air, and then immersed in a solder bath, to thereby coat the electrodes with a solder. After the solder coating, ultrasonic cleaning is repeated a several times at normal temperature or in warm water, and rinsed, and then dried with warm air. Thereafter, a solder-coated copper lead is placed on the solder-coated electrodes, and heat-treated to perform soldering. This process is repeated on the front surface and the back surface of the solar battery element to form strings, so as to produce a solar battery module.

Thus, the process for producing a solar battery module is complicated and has problems, such as warpage and cracks of the silicon substrate, and electrode detachment, occurring due to heat stress upon soldering an interconnector, causing decrease in yield.

Moreover, in recent years, the thickness of silicon substrates tends to be thinner because of cost reduction, and the like. In the past, the thickness of silicon substrates has been approximately 300 μm to 500 μm, but recently silicon substrates having less than 200 μm have became a mainstream. Hereafter, there is a high possibility that the silicon substrates are getting much thinner, and problems, such as the warpage and cracks of the silicon substrate, and electrode detachment due to heat stress upon soldering an interconnector, easily and more markedly occur, and these problems must be solved.

As a means for solving these problems, a method for producing a solar battery module, which includes the first step in which a solder is melted, and the second step in which a solar battery element is kept at an ambient temperature, which is lower than the melting temperature of the solder and higher than room temperature, for a predetermined time, is proposed in PTL 1. Moreover, a solar battery cell, in which a reinforcement material formed of baked silver is applied to at least a part of around the back surface of the solar battery cell, is proposed in PTL 2. However, these techniques have not been satisfied, and further improvement is demanded.

Moreover, in terms of environmental problems, in recent years a lead-free solder is preferred. However, it is concerned that the soldering using a lead-free soldering needs high temperature, causes problems such as warpage, cracks, and results in low strength.

### CITATION LIST

### Patent Literature

PTL 1 Japanese Patent Application Laid-Open (JP-A) No. 2006-332264

PTL 2 JP-A No. 2006-319376

### SUMMARY OF INVENTION

The present invention solves the conventional problems and achieves the following object. That is, the present invention provides a solar battery having high conversion efficiency and reliability, and a method for producing a solar battery, which does not require soldering, causes less load on environment, and can inhibit cracks and warpage of the solar battery element, and separation of an interconnector, thereby producing the solar battery with ease and efficiency.

The inventors of the present invention have been intensively studied the above problems, and obtained the following findings. That is, when an interconnection of solar battery elements is achieved by bonding a transparent conductive film, the soldering step in the conventional method for producing a solar battery is not required, the cracks and warpage of the solar battery element and separation of the interconnector can be inhibited and environmental load is reduced. Thus, a solar battery having high reliability can be provided. The conversion efficiency of the solar battery can be improved by reducing light shielding ratio, and improving electrical contact ratio of electrodes of the solar battery element.

The presents invention is based on the above-described findings and a means for solving the problems are as follows.

<1> A solar battery including: a transparent conductive film; and a solar battery element, wherein the transparent conductive film is bonded to a surface of the solar battery element, and the transparent conductive film is electrically connected to the solar battery element.

<2> The solar battery according to <1>, wherein the solar battery includes two or more solar battery elements, and the two or more solar battery elements are electrically connected with each other in series or in parallel.

<3> The solar battery according to any one of <1> and <2>, wherein the solar battery element is electrically connected with each other in series or in parallel through the transparent conductive film.

<4> The solar battery according to any one of <1> to <3>, wherein a conductive electrode is electrically connected to a surface of the solar battery element.

<5> The solar battery according to <4>, wherein the conductive electrode is electrically connected to both of a light receiving surface and a non-light receiving surface of the solar battery element.

<6> The solar battery according to any one of <1> to <5>, wherein the transparent conductive film includes a film substrate and a conductive layer.

<7> The solar battery according to <6>, wherein the conductive layer contains a metal mesh.

<8> The solar battery according to <6>, wherein the conductive layer contains a binder and conductive fibers.

<9> The solar battery according to any one of <1> to <5>, wherein the transparent conductive film contains a binder and a conductive material.

<10> The solar battery according to <9>, wherein the conductive material is any one of a metal mesh and conductive fibers.

<11> The solar battery according to any one of <8> and <10>, wherein the conductive fibers are any one of carbon nanotubes and metal nanowires.

<12> The solar battery according to <11>, wherein the metal nanowire is a silver nanowire.

<13> A method for producing a solar battery, including: forming electrodes on both surfaces of a substrate so as to produce a solar battery element; bonding a transparent conductive film to a plurality of the solar battery elements so as to interconnect the solar battery elements in series or in parallel; and sealing the solar battery elements.

<14> The method for producing a solar battery according to <13>, wherein the transparent conductive film includes a film substrate and a conductive layer.

<15> The method for producing a solar battery according to <14>, wherein the conductive layer contains a metal mesh.

<16> The method for producing a solar battery according to <14>, wherein the conductive layer contains a binder and conductive fibers.

<17> The method for producing a solar battery according to <13>, wherein the transparent conductive film contains a binder and a conductive material.

<18> The method for producing a solar battery according to <17>, wherein the conductive material is any one of a metal mesh and conductive fibers.

<19> The method for producing a solar battery according to any one of <16> and <18>, wherein the conductive fibers are any one of carbon nanotubes and metal nanowires.

<20> The method for producing a solar battery according to <19>, wherein the metal nanowire is a silver nanowire.

The present invention can solve the conventional problems and provide a solar battery having high conversion efficiency and reliability, and a method for producing a solar battery does not require soldering, causes less load on environment, can inhibit cracks and warpage of the solar battery element, and separation of an interconnector, thereby producing the solar battery with ease and efficiency.

### BRIEF DESCRIPTION OF DRAWINGS

FIG. 1 is a schematic explanatory view showing an example of an embodiment, in which solar battery elements are connected to a transparent conductive film having conductivity in both surfaces thereof.

FIG. 2 is a schematic explanatory view showing an example of an embodiment, in which solar battery elements are connected to a transparent conductive film having conductivity in one of surfaces thereof.

FIG. 3 is a schematic explanatory view showing an example of a solar battery of the present invention.

FIG. 4 is a flow chart showing an example of a step of producing a conventional solar battery module.

FIG. 5 is a flow chart showing an example of a step of producing a solar battery module of the present invention.

FIG. 6A is a top view of a solar battery element in the solar battery of Comparative Example 1.

FIG. 6B is a cross-sectional view of the solar battery of Comparative Example 1.

FIG. 7A is a top view of a solar battery element in the solar battery of Example 1.

FIG. 7B is a cross-sectional view of the solar battery of Example 1.

FIG. 8A is a top view of solar battery elements in the solar battery of Comparative Example 2.

FIG. 8B is a cross-sectional view of the solar battery of Comparative Example 2.

FIG. 9A is a top view of solar battery elements in the solar battery of Example 2.

FIG. 9B is a cross-sectional view of the solar battery of Example 2.

### DESCRIPTION OF EMBODIMENTS

### (Solar Battery)

A solar battery of the present invention includes a transparent conductive film, and a solar battery element, wherein the transparent conductive film is bonded to a surface of the solar battery element, and further includes appropriately selected other members as necessary. The solar battery element is electrically connected to the transparent conductive film.

### <Solar Battery Element>

The solar battery element includes at least a substrate and a conductive electrode, and further includes other members as necessary.

### —Substrate—

The shape, structure, size, thickness and material of the substrate is suitably selected depending on the intended purpose without any restriction. Examples of the material for the substrate include a single-crystal silicon, and a polycrystalline silicon.

Inside of the substrate, a p-n junction is formed by bringing a p-layer containing a large amount of p-type impurities such as boron into contact with an n-layer containing a large amount of n-type impurities such as phosphorus. The n-layer is formed at the side of a light receiving surface of the substrate, and the p-layer is formed at the side of a non-light receiving surface of the substrate. On the n-layer and the p-layer, a negative electrode and a positive electrode described below are respectively formed using a silver paste, an aluminum paste, and the like.

### —Conductive Electrode—

The conductive electrode is electrically connected to a surface of the solar battery element (the substrate), and preferably electrically connected to both of a light receiving surface and a non-light receiving surface (back surface) of the solar battery element. Here, the conductive electrode formed on the light receiving surface of the substrate is a positive electrode and the conductive electrode formed on the non-light receiving surface of the substrate is a negative electrode.

The negative electrode in the non-light receiving surface may be formed in a linear shape or dot shape using a silver paste, or formed in a planer shape using an aluminum paste. The negative electrode is preferably formed in a planer shape using an aluminum paste, and then formed in a linear shape or dot shape using a silver paste on an aluminum paste.

The positive electrode in the light receiving surface may be formed with a silver paste in the shape of fingers with certain intervals so as to cover the light receiving surface with the fingers of the silver paste. In the present invention, the positive electrode on the light receiving surface is preferably formed with a silver paste in the shape of dots with certain intervals so as to cover the light receiving surface with the dots of the silver paste, in terms of increase in the amount of the received light of the solar battery element.

The typical interconnector of a copper foil is formed in a finger shape so as to collect electricity, but the solar battery of the present invention can collect electricity from the whole light receiving surface, and the electrodes may be formed in the shape of dots in the present invention. In this case, the electrode area of the light receiving surface can be decreased, and the amount of the received light of the solar battery element can be increased.

The solar battery element has the transparent conductive film, which is bonded to a surface of the solar battery element.

### <Transparent Conductive Film>

The thickness of the transparent conductive film is suitably selected depending on the intended purpose without any restriction. It is preferably 1 μm to 300 μm, and more preferably 2 μm to 200 μm.

When the thickness is less than 1 μm, the transparent conductive film is not strong enough as the interconnector, causing decrease in reliability. When it is more than 300 μm, the transparent conductive film becomes thicker than the substrate of the solar battery, causing difficulty in handling upon interconnecting.

The surface resistance of the transparent conductive film is suitably selected depending on the intended purpose without any restriction. It is preferably 0.1 Ω/sq to 200 Ω/sq, more preferably 0.5 Ω/sq to 100 Ω/sq, and even more preferably 1 Ω/sq to 50 Ω/sq.

When the surface resistance is less than 0.1 Ω/sq, the transmittance is decreased, causing decrease in the conversion efficiency. When the surface resistance is more than 200 Ω/sq, the conversion efficiency may be decreased due to resistance loss.

The total light transmittance of the transparent conductive film is suitably selected depending on the intended purpose without any restriction. It is preferably 50% to 100%, more preferably 70% to 99%, even more preferably 80% to 98%.

When the total light transmittance is less than 50%, the conversion efficiency may be significantly decreased.

The transparent conductive film is exemplified by the first embodiment in which the transparent conductive film contains a film substrate and a conductive layer, and the second embodiment in which the transparent conductive film contains a binder and a conductive material.

In the first embodiment, the transparent conductive film basically has conductivity in one of surfaces thereof, but the transparent conductive film can have conductivity in both surfaces thereof by using the film substrate having conductivity.

In the second embodiment, the transparent conductive film may have conductivity in one of surfaces thereof, but preferably have conductivity in both surfaces thereof.

### First Embodiment of Transparent Conductive Film

The transparent conductive film of the first embodiment includes at least a film substrate and a conductive layer, and further includes appropriately selected other members as necessary.

### —Film Substrate—

The film substrate is suitably selected depending on the intended purpose without any restriction, but preferably has flexibility, for example, a polymer film formed of acrylic resins such as polycarbonate, polymethacrylate; vinyl chloride resins, such as polyvinyl chloride, vinyl chloride copolymer; thermoplastic resins such as polyarylate, polysulfone; polyether sulfone; polyimide; PET; PEN; fluororesin; phenoxy resins; polyolefine resins; nylon; styrene resins; and ABS resins.

### —Conductive Layer—

The conductive layer is suitably selected depending on the intended purpose without any restriction. It is preferred that the conductive layer be formed of a metal mesh, or contain a binder and conductive fibers.

### ——Metal Mesh——

The metal mesh is suitably selected depending on the intended purpose without any restriction. The metal mesh preferably has an opening, which can be formed by the following methods.

### (1) Electroless Plating Processed Mesh

A method in which an electroless-plating catalyst is printed in a grid pattern by a printing method, and then the electroless-plating is performed (for example, JP-A Nos. 11-170420, 05-283889, etc.). A method in which a photoresist containing an electroless-plating catalyst is applied, followed by exposing and developing to form a pattern of the electroless-plating catalyst, and then electroless-plating is performed (for example, JP-A No. 11-170421).

### (2) Silver Paste Printed Mesh

A method of obtaining a silver mesh by printing a silver powder paste (JP-A Nos. 2000-13088, and 2000-24485).

### (3) Mesh Etched by Use of Photolithography

A method in which a thin film of metal mesh is formed on a transparent substrate by etching process using photolithography (JP-A Nos. 2003-46293, 2003-23290, 05-16281 and 10-338848).

### (4) Method of Forming Conductive Metal Silver Pattern Using Silver Halide Photosensitive Material

A method of forming a thin film pattern of metal silver by the use of a silver salt diffusion transfer process, in which silver is deposited on a physical development nuclei (Japanese Patent Application Publication (JP-B) Nos. 42-23746, 43-12862, “Analytical Chemistry”, Vol. 72, 645 (2000), International Publication No. WO 01/51276, JP-A Nos. 2000-149773, 2004-221564, and 2004-221565).

### ——Binder——

The binder is suitably selected depending on the intended purpose without any restriction, but a polymer is preferably used.

The polymer is suitably selected depending on the intended purpose without any restriction. Examples thereof include polyacrylic acid such as polymethacrylate, (for example, poly(methyl methacrylate)), polyacrylate, polyacrylonitrile; polyvinyl alcohol; polymers having high aromaticity such as polyester, (for example, polyethylene terephthalate (PET), polyesternaphthalate, polycarbonate), phenol or creosol-formaldehyde (NOVOLAC); polystylene, polyvinyl toluene, polyvinyl xylene, polyimide, polyamide, polyamide-imide, polyether amide, polysulfide, polysulfone, polyphenylene, polyphenylether, polyurethane (PU), epoxy, polyolefin (for example, polypropylene, polymethylpentene, and cyclic olefin), acrylonitrile-butadiene-styrene copolymer (ABS), cellulose and derivative therof, silicone and polymer containing silicon (for example, polysilsesquioxane and polysilane), polyvinyl chloride (PVC), polyacetate, polynorbornene, synthetic rubber, (for example, EPR, SBR, EPDM) and fluoropolymer (for example, polyvinylidene fluoride, polytetrafluoroethylene (PTFE), or polyhexafluoropropylene), copolymers of fluoro-olefin and hydrocarbon olefin (for example, LUMIFLON), amorphous fluorocarbon polymer or copolymer (for example, CYTOP manufactured by ASAHI GLASS CO., LTD., or TEFLON AF manufactured by DuPont), gelatin, carrageenan, polyvinyl pyrrolidone (PVP), polysaccharide such as starch, polyethylene oxide, polyvinylamine, chitosan, polylysine, polyalginic acid, polyhyaluronic acid, and carboxycellulose.

### ——Conductive Fiber——

The conductive fiber is suitably selected depending on the intended purpose without any restriction. Examples thereof include ultrafine fibers, metal nanotubes, metal nanowires, metal oxide nanotubes, and metal oxide nanowires.

Examples of the ultrafine fibers include carbon nanotubes, carbon nanohorns, carbon nanowires, carbon nanofiber, and graphite fibrils.

Examples of the metals of the metal nanotubes and metal nanowires include platinum, gold, silver, nickel, and silicon.

As the metal oxide of the metal oxide nanotubes or the metal oxide nanowires, zinc oxide is exemplified.

Of the conductive fibers, the metal nanowires and the carbon nanotubes are preferable, and the metal nanowires are particularly preferably used in terms of satisfying both transparency and conductivity.

### [Metal Nanowire]

The metal nanowire is suitably selected depending on the intended purpose without any restriction. As the metal nanowire, metal oxides such as ITO, zinc oxide, tin oxide; and metallic carbon nanotubes may be exemplified. A core shell structure consisting of a metal element or a plurality of metal elements, an alloy, and a metal plated nanowire are preferably exemplified.

The diameter (minor axis length) of the metal nanowire is preferably 300 nm or less, more preferably 200 nm or less, even more preferably 100 nm or less. When the diameter thereof is too small, the antioxidation property thereof is degraded, adversely affecting the durability of the metal nanowire. Therefore, the diameter of the metal nanowire is preferably 5 nm or more. When the diameter thereof is more than 300 nm, there are cases where sufficient transparency cannot be attained, probably because the scattering is occurred due to the metal nanowires.

The major axis length of the metal nanowire is preferably 5 μm or more, more preferably 15 μm or more, even more preferably 25 μm or more. When the major axis length of the metal nanowire is too long, aggregated matters may be generated during the production probably because the metal nanowires are tangled each other. Therefore, the major axis length of the metal nanowire is preferably 1 mm or less, and more preferably 500 μm or less. When the major axis length of the metal nanowire is less than 5 μm, sufficient conductivity may not be attained probably because it is difficult to form a dense network.

Here, the diameter and major axis length of the metal nanowire can be obtained, for example, by using a transmission electron microscope (TEM) and an optical microscope, and observing images of the TEM or optical microscope.

### <Method for Producing Metal Nanowire>

The metal nanowire may be produced by any method without any restriction, but it is preferably produced by reducing a metal ion in a solvent in which a halogen compound and a dispersing agent are dissolved as described below.

As the solvent, a hydrophilic solvent is preferably used. Examples of the hydrophilic solvent include: water; alcohols such as methanol, ethanol, propanol; isopropanol, butanol, and ethylene glycol; ethers such as dioxane, and tetrahydrofuran; and ketones such as acetone.

The heating temperature is preferably 250° C. or less, more preferably 20° C. to 200° C., even more preferably 30° C. to 180° C., particularly preferably 40° C. to 170° C. If necessary, the temperature may be changed during the formation of particles. To change the temperature in the middle of the formation of particles may contribute to the control for the formation of the core, preventing the generation of re-grown cores, and selective acceleration of the growth to thereby improve the monodispersibility.

When the heating temperature is more than 250° C., the trasmittance may be lowered in terms of the evaluation of the coated film, probably because the angles of the cross section of the metal nanowire become sharp. Moreover, as the heating temperature is getting lower, the metal nanowires tends to tangle and dispersion stability thereof is lowered, probably because the yield of core is lowered and the metal nanowires become too long. This tendency becomes significant at the heating temperature of 20° C. or less.

It is preferred that the reducing agent be added at the time of the heating. The reducing agent is suitably selected from those generally used without any restriction. Examples of the reducing agent include: metal salts of boron hydrides such as sodium boron hydride and potassium boron hydride; aluminum salt hydrides such as lithium aluminum hydride, potassium aluminum hydride, cesium aluminum hydride, beryllium aluminum hydride, magnesium aluminum hydride, and calcium aluminum hydride; sodium sulfites; hydrazine compounds; dextrins; hydroquinones; hydroxyl amines; citric acids and salts thereof; succinic acid and salts thereof; ascorbic acids and salts thereof; alkanol amines such as diethylamino ethanol, ethanol amine, propanol amine, triethanol amine, and dimethylamino propanol; aliphatic amines such as propyl amine, butyl amine, dipropylene amine, ethylene diamine, and triethylenepentane amine; heterocyclic amines such as piperidine, pyrrolidine, N-methyl pyrrolidine, and morpholine; aromatic amines such as aniline, N-methyl aniline, toluidine, anisidine, and phenetidine; aralkyl amines such as benzyl amine, xylene diamine, and N-methylbenzyl amine; alcohols such as methanol, ethanol and 2-propanol;ethylene glycol; glutathione; organic acids such as citric acid, malic acid, and tartaric acid; reducing sugars such as glucose, galactose, mannose, fructose, sucrose, maltose, raffinose, and stachyose; and sugar alcohols such as sorbitol. Of these, the reducing sugars and sugar alcohols that are derivatives of the reducing sugars, and ethylene glycol are particularly preferable.

Note that, there is a case where the reducing agents may also function as a dispersing agent, and a solvent depending on the types of the reducing agents for use, and those reducing agents are also preferably used.

The timing for adding the reducing agent may be before or after adding a dispersing agent, and may be before or after adding a halogen compound or halogenated metal fine particles.

It is preferred that the dispersing agent and the halogen compound or halogenated metal fine particles be added at the time of the formation of the metal nanowires.

The timing for adding the dispersing agent and the halogen compound may be before or after adding the reducing agent, and may be before or after adding the metal ion or the halogenated metal fine particles. In order to obtain more highly monodispersible nanowires, the addition of the halogen compound is preferably carried out more than twice to control formation and growth of cores.

The timing for adding the dispersing agent may be before preparing particles in the presence of dispersion polymer, or after preparing particles for controlling the dispersion state of the particles. In the case where the addition of the dispersing agent is carried out more than twice, the amount of the dispersion agent to be added each time needs to be adjusted depending on the desired length of the metal wires. This is because it is considered that the length of the metal wires is affected by the control of the amount of the metal particles serving as cores.

Examples of the dispersing agent include amino group-containing compounds, thiol group-containing compounds, sulfide group-containing compounds, amino acids or derivatives thereof, peptide compounds, polysaccharides, natural polymers derived from polysaccharides, synthetic polymers, and polymers derived from those mentioned above such as gels.

Examples of the polymers include protective colloid polymers such as gelatin, polyvinyl alcohol (P-3), methyl cellulose, hydroxypropyl cellulose, polyalkylene amine, partial alkyl ester of polyacrylic acid, polyvinyl pyrrolidone, and polyvinyl-pyrrolidine copolymer.

The compound structures usable for the dispersing agent can be, for example, referred to the description in Pigment Dictionary (edited by Seishiro Ito, published by ASAKURA PUBLISHING CO., (2000)).

Depending on the type of the dispersing agent for use, shapes of obtained metal nanowires can be changed.

The halogen compound is suitably selected depending on the intended purpose without any restriction, as long as the compound contains bromine, chlorine, or iodine. Preferable examples of the halogen compound include: alkali halide such as sodium bromide, sodium chloride, sodium iodide, potassium bromide, potassium chloride, and potassium iodide; and compounds that can be used together with the dispersing agent described below. The timing for adding the halogen compound may be before or after adding the dispersing agent, and before or after adding the reducing agent.

The halogen compounds may also function as a dispersing agent depending on the types of the halogen compounds for use, and those halogen compounds are also preferably used.

Halogenated silver fine particles may be used as a replacement of the halogen compound, or the halogen compound and the halogenated silver fine particles may be used in combination.

The dispersing agent and the halogen compound or halogenated silver fine particles may be formed of the same material. The compound used for both the dispersing agent and the halogen compound is, for example, hexadecyl trimethyl ammonium bromide (HTAB) containing amino group and bromide ion, or hexadecyl trimethyl ammonium chloride (HTAC) containing amino group and chloride ion.

The desalination can be carried out by ultrafiltration, dialysis, gel filtration, decantation, centrifugal separation, or the like, after forming the metal nanowires.

It is preferred that the metal nanowires do not contain inorganic ions such as alkali metal ions, alkali earth ions, and halide ions as much as possible. The electric conductivity of the aqueous dispersion of the metal nanowires is preferably 1 mS/cm or less, more preferably 0.1 mS/cm or less, even more preferably 0.05 mS/cm or less.

The viscosity of the aqueous dispersion of the metal nanowires at 20° C. is preferably 0.5 mPa·s to 100 mP·s, more preferably 1 mPa·s to 50 mPa·s.

### [Carbon Nanotube]

The carbon nanotube is a tube-shaped carbon formed of an elongated carbon having a fiber diameter of 1 nm to 1,000 nm, a length of 0.1 μm to 1,000 μm, and an aspect ratio of 100 to 10,000.

As a method for producing the carbon nanotube, an arc discharge method, a laser vaporization method, a thermal CVD method, and a plasma CVD method are known. The carbon nanotubes obtained by the arc discharge method, and the laser vaporization method are classified into a single wall carbon nanotube (SWNT) having a layer of a graphene sheet and a multi wall carbon nanotube (MWNT) having a plurality of graphene sheets.

In general, MWNT is produced by thermal CVD methods and plasma CVD methods. In the SWNT, a graphene sheet, in which carbon atoms are bound to each other via a strong bond called an SP2 bond so as to form six-membered rings, is rolled into a tube.

The carbon nanotube (SWNT, MWNT) is a tube-shaped material having a structure in which one to several graphene sheets is/are rolled into a tube, and having a diameter of 0.4 nm to 10 nm and a length of 0.1 μm to several 100 μm. The carbon nanotube has unique properties that it functions as a metal or a semiconductor depending on the direction into which the graphene sheet is rolled.

The amount of the conductive fibers in the conductive layer is preferably 1 part by mass to 1,000 parts by mass, relative to 100 parts by mass of a binder.

When the amount of the conductive fibers is less than 1 part by mass, the conductivity is significantly decreased. When the amount of the conductive fibers is more than 1,000 parts by mass, the film strength of the conductive layer, particularly, mechanical properties such as adhesion may be decreased.

### Second Embodiment of Transparent Conductive Film

In the second embodiment, the transparent conductive film contains at least a binder and a conductive material, and further contains appropriately selected other components as necessary.

The binder is suitably selected depending on the intended purpose without any restriction, and the same as those in the transparent conductive film of the first embodiment can be used.

The conductive material is suitably selected depending on the intended purpose without any restriction. For example, a metal mesh, conductive fibers, and the like are preferably used.

The metal mesh and the conductive fibers are suitably selected depending on the intended purpose without any restriction, and the same as those in the transparent conductive film of the first embodiment can be used.

The transparent conductive film of the second embodiment can be formed in such a manner that a transparent conductive part containing the conductive material and the binder is formed on a substrate, and then the transparent conductive part is separated from the substrate, to thereby obtain the transparent conductive film.

The amount of the conductive fibers in the transparent conductive film is 1 part by mass to 1,000 parts by mass, relative to 100 parts by mass of the binder.

When the amount of the conductive fibers is less than 1 part by mass, the conductivity may be remarkably decreased. When the amount is more than 1,000 parts by mass, the film strength of the transparent conductive film, particularly, mechanical properties such as adhesion may be decreased.

### —Bonding of Solar Battery Element to Transparent Conductive Film—

In the solar battery of the present invention, the transparent conductive film is bonded to a surface of the solar battery element. This is advantageous in that the solar battery does not require soldering, and has a less load on environment, and that cracks and warpage of the solar battery element, and separation of interconnector can be inhibited.

The transparent conductive film is preferably bonded to the light receiving surface of the solar battery element.

In the case of the transparent conductive film of the first embodiment containing the film substrate and the conductive layer, the transparent conductive film is bonded to the solar battery element in such a manner that the conductive layer faces to the solar battery element.

The electrode of the light receiving surface of the solar battery element is preferably formed in a finger shape using a silver paste. The electrode of the light receiving surface is more preferably formed in a dot shape as the light shielded area can be made smaller. When the electrode is formed in the dot shape, the dots may be uniformly arranged all over the light receiving surface, or may be randomly arranged over the light receiving surface.

The area of the transparent conductive film in contact with the solar battery element is suitably selected depending on the intended purpose without any restriction. It is preferably 10% or more, more preferably 30% or more, even more preferably 50% or more, with respect to the area of the solar battery element.

When the contact area is less than 10%, the contact resistance increases, and the conversion efficiency may not be sufficiently obtained.

The thickness, structure, size, material of the solar battery element is suitably selected depending on the intended purpose without any restriction.

The size is preferably approximately 50 mm×50 mm to approximately 300 mm×300 mm, and more preferably approximately 100 mm×100 mm to approximately 200 mm×200 mm.

The thickness is suitably selected depending on the intended purpose without any restriction. It is preferably 50 μm to 500 μm, more preferably 100 μm to 300 μm.

The material is suitably selected depending on the intended purpose without any restriction. For example, a single crystalline silicon or polycrystalline silicon is preferably used.

### —Interconnection Method—

Two or more solar battery elements are preferably electrically connected in series or in parallel.

As a method of connecting in series or in parallel, the solar battery elements are connected to each other through the transparent conductive film bonded to the surface of the solar battery element. Here, when two solar battery elements are connected in series through the transparent conductive film having conductivity in both surfaces thereof, the transparent conductive film is bonded to the light receiving surface of one solar battery element and to the non-light receiving surface of the other solar battery element. Thus, the two solar battery elements are connected in series.

Moreover, solar battery elements may be connected to each other by connecting the transparent conductive films, which are respectively bonded to the solar battery elements. Here, in the case where two solar battery elements are connected in series, the two transparent conductive films are preferably connected in the following manner: one transparent conductive film is bonded to the light receiving surface of one solar battery element, the other transparent conductive film is bonded to the non-light receiving surface of the other solar battery element, and then these two transparent conductive films are connected to each other. This embodiment is particularly preferred in the case of the transparent conductive film in which only one surface has a conductive part, since it is necessary to connect the transparent conductive films to each other.

The connection between the solar battery element and the transparent conductive film will be further described by way of specific examples, but not limited thereto.

(1) An embodiment in which the solar battery elements are connected in series through the transparent conductive film having conductivity in both surfaces thereof.

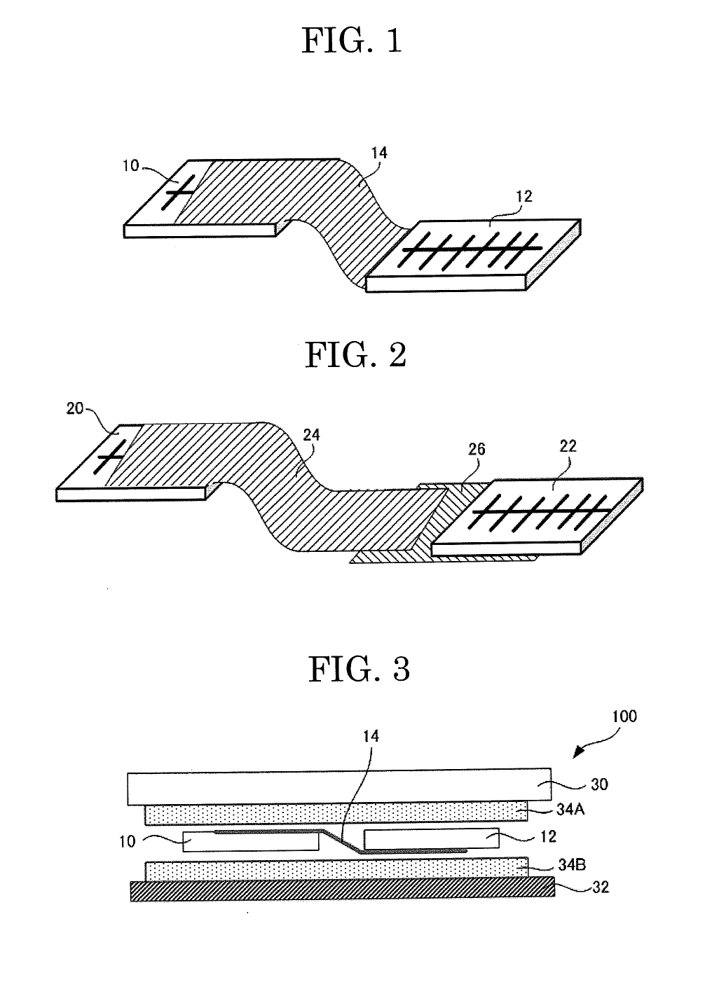

As shown in FIG. 1, a transparent conductive film 14 having conductivity in both surfaces thereof is bonded to a light receiving surface of a solar battery element 10, and a non-light receiving surface of a solar battery element 12, to thereby connect the solar battery element 10 and the solar battery element 12 in series.

Here, the transparent conductive film 14 may be connected with the respective solar battery elements 10 and 12 by bonding them using a conductive adhesive. However, it is preferred that the transparent conductive film 14 can be connected with the respective solar battery elements 10 and 12 only by pressure bonding at the time of the EVA sealing described below.

(2) An embodiment in which the solar battery elements are connected in series through the transparent conductive films having conductivity in one of surfaces thereof.

As shown in FIG. 2, the transparent conductive film 24 having conductivity in one of surfaces thereof is bonded to a light receiving surface of a solar battery element 20, the transparent conductive film 26 having conductivity in one of surfaces thereof is bonded to a non-light receiving surface of a solar battery element 22, and then the transparent conductive film 24 is connected with the transparent conductive film 26, to thereby connect the solar battery element 20 with the solar battery element 22 in series.

Here, the transparent conductive film 24 and the transparent conductive film 26 may be connected between the solar battery element 20 and the solar battery element 22, on the solar battery element 20, or on the solar battery element 22. The transparent conductive film 24 and the transparent conductive film 26 are preferably connected on the solar battery element 22. The connection of the transparent conductive films causes decrease in transmittance, since two transparent conductive films are overlapped. On the other hand, since the connection of the transparent conductive films on the solar battery element 22 is achieved on the non-light receiving part, it is advantageous in that the connection of the transparent conductive films does not influence on decrease in the transmittance.

The transparent conductive films 24 and 26 may be connected by bonding them using the conductive adhesive described above, or using a silver paste. It is preferred that the transparent conductive films 24 and 26 can be connected only by pressure bonding at the time of the EVA sealing described below.

Parallel connection can be achieved by the same method as described above.

By the use of the interconnection method, a plurality of solar battery elements are connected in series or in parallel, to thereby form a solar battery module.

A method for producing a solar battery of the present invention is not particularly limited, and a solar battery module can be formed by generally performed methods. A solar battery is preferably produced by the method for producing a solar battery of the present invention, which will be described below.

Here, the solar battery module means a plurality of the solar battery elements connected in series or in parallel.

As shown in FIG. 3, a solar battery (solar battery module) 100 of the present invention is basically constituted with solar battery elements 10 and 12 connected in series or in parallel through a transparent conductive film 14, a glass substrate 30 as a transparent protective member of the light receiving surface, a protective member of the back surface (back cover) 32, and ethylene-vinyl acetate copolymer (EVA) films 34A and 34B as the sealing films, but not limited thereto. For example, as the sealing film, polyvinyl butyral (PVB) can also be preferably used.

Such solar battery module is obtained in such a manner that the glass substrate 30, the EVA film for sealing 34A, the solar battery elements 10 and 12, an EVA film for sealing 34B and the back cover 32 are layered in this order, and the EVA films 34A and 34B are heat-melted, crosslinked and cured, so as to integrally bond layers.

In the solar battery of the present invention, the transparent conductive film as the interconnector is bonded to the solar battery element so as to attain electrical connection. Thus, the solar battery of the present invention does not require soldering, although the conventional solar battery requires soldering, and the solar battery of the present invention has a less load on environment, and cracks and warpage of the solar battery element, and separation of the interconnector can be inhibited. Thus, the solar battery of the present invention has high conversion efficiency and high reliability.

### (A Method for Producing Solar Battery)

A method for producing a solar battery of the present invention includes at least a step of producing a solar battery element, an interconnecting step, and a sealing step, and further includes appropriately selected other steps, as necessary.

### <Step of Producing Solar Battery Element>

A step of producing a solar battery element is a step in which electrodes are formed on both surfaces of a substrate so as to produce a solar battery element.

The detail of the solar battery element is as specifically described in the description of the solar battery of the present invention. The solar battery element can be produced by forming a p-n junction inside of the substrate, and further forming conductive electrodes corresponding to an n-layer and a p-layer on a surface of the substrate.

### <Interconnecting Step>

The interconnecting step is a step of bonding a transparent conductive film to a plurality of solar battery elements so as to interconnect the solar battery elements in series or in parallel.

The detail of the transparent conductive film, the solar battery element, and the bonding of the transparent conductive film to the solar battery element are as specifically described in the description of the solar battery of the present invention.

### <Sealing Step>

The sealing step is a step of sealing the solar battery element after the interconnecting step.

A sealing method is suitably selected depending on the intended purpose without any restriction. For example, the sealing can be achieved in such a manner that an ethylene-vinyl acetate copolymer (EVA) film, a polyvinyl butyral (PVB) film, or the like are used as a sealing film, and the sealing films are heat-melted, crosslinked and cured, so as to integrally bond layers.

### [Comparison Between a Convention Method for Producing a Solar Battery and a Method for Producing a Solar Battery of the Present Invention]

### —Conventional Method for Producing Solar Battery Module—

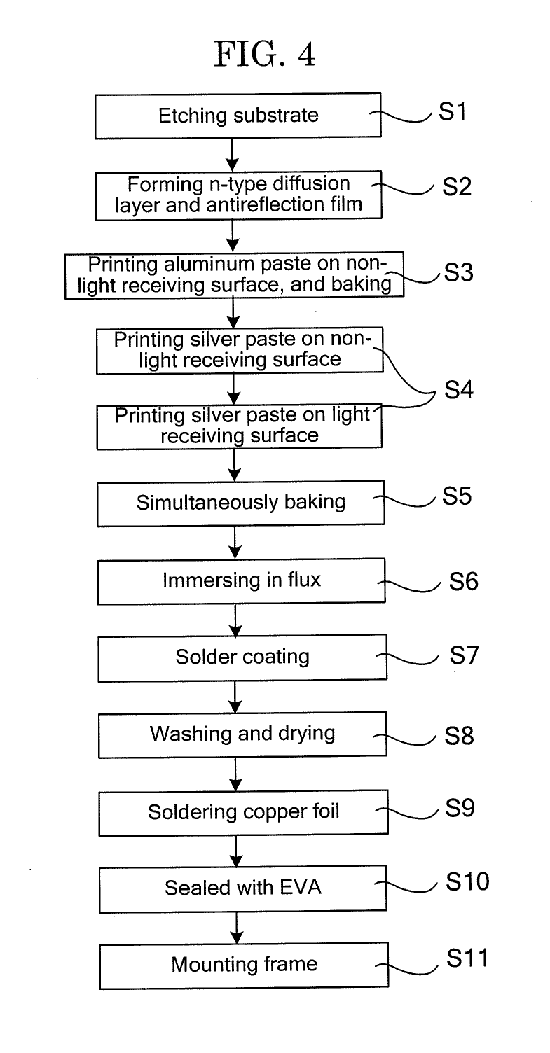

A step of producing a typical solar battery module is shown in FIG. 4. (see JP-A No. 2006-49429).

Firstly, in Step S1, a p-type Si substrate is etched. Next, in Step S2, on a light receiving surface of the p-type Si substrate, an n-type diffusion layer, and an antireflection film for decreasing a reflectance of sunlight are formed. Next, in Step S3, on a substantially whole surface of the back surface of the p-type Si substrate, an Al paste is screen printed and dried, and then baked at high temperature of approximately 700° C. under oxidizing atmosphere, so as to form an Al electrode. In Step S4, on a part of the back surface of the p-type Si substrate, an Ag paste is screen printed, and on the antireflection film of the light receiving surface of the p-type Si substrate, an Ag paste is screen printed in a finger shape, and the Ag paste is dried at a temperature of approximately 150° C. Then in Step S5, the Ag paste is screen printed on the antireflection film and a part of the back surface of the p-type Si substrate is baked at a high temperature of approximately 620° C. for approximately 1 minute to approximately 2 minutes, to thereby form Ag electrodes on both surfaces of the p-type Si substrate. Thereafter, in Step S6, the p-type Si substrate on which the Ag electrodes are formed is immersed in flux, and dried with hot air. Next, in Step S7, the p-type Si substrate is immersed in a solder bath at approximately 200° C. for approximately 1 minute, to coat the Ag electrode with the solder. Then, in Step S8, the Ag electrode is washed and subjected to reflow, to thereby obtain a solar battery element. In Step S9, in a state where a solder layer of the Ag electrode is in contact with a solder layer is formed in the interconnector such as copper foil, hot air at 400° C. is blown to the interconnector. By this way, the solder layers are melted, and cooled to be solidified, to thereby electrically connect the Ag electrode and the interconnector. Moreover, after a plurality of solar battery elements are electrically connected in series or in parallel through the interconnector, in Step 10, the solar battery elements are sealed with the EVA films, and in Step 11 a frame is mounted to thereby obtain a solar battery module.

Thus, the conventional method for producing a solar battery module is complicated, and includes many steps. Particularly, the step of connecting the interconnector is complicated and needs a high temperature process, thus the warpage or cracks are caused in the Si solar battery element.

### —Method for Producing Solar Battery Module of the Present Invention—

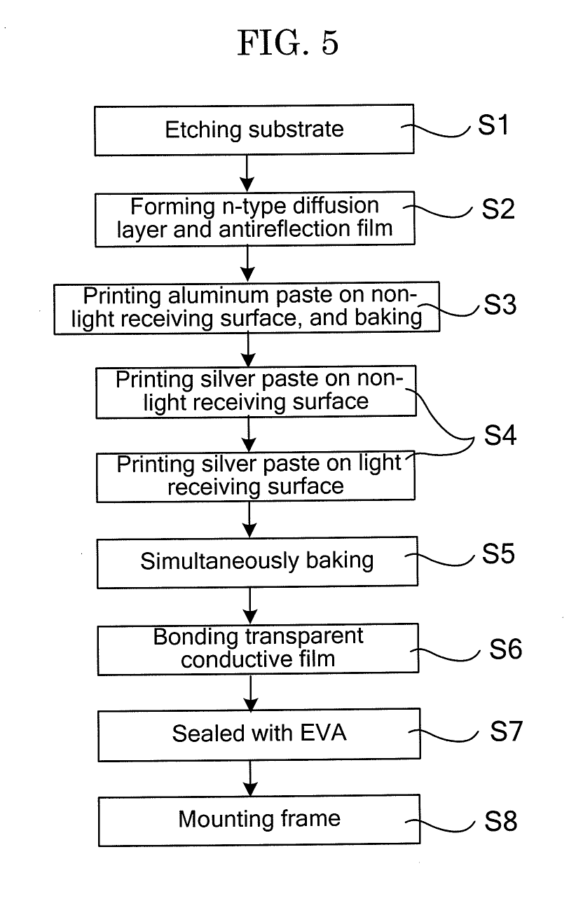

An example of a step of producing a module using a solar battery element of the present invention is shown in FIG. 5.

Firstly, in Step S1, a p-type Si substrate is etched. Next, in Step S2, on a light receiving surface of the p-type Si substrate, an n-type diffusion layer, and an antireflection film for decreasing a reflectance of sunlight are formed. Next, in Step S3, on a substantially whole surface of the back surface of the p-type Si substrate, an Al paste is screen printed and dried, and then baked at high temperature of approximately 700° C. under oxidizing atmosphere, so as to form an Al electrode. In step S4, on a part of the back surface of the p-type Si substrate, an Ag paste is screen printed, and on the antireflection film of the light receiving surface of the p-type Si substrate, an Ag paste is screen printed in a finger shape (or in a dot shape, in the case of the present invention), and the Ag paste is dried at a temperature of approximately 150° C. Then in Step S5, the Ag paste is screen printed on the antireflection film and a part of the back surface of the p-type Si substrate is baked at a high temperature of approximately 620° C. for approximately 1 minute to approximately 2 minutes, to thereby form Ag electrodes on both surfaces of the p-type Si substrate. Thereafter, in Step S6, the transparent conductive film is electrically connected to the Ag electrode in the solar battery cell. A plurality of solar battery elements are connected in series or in parallel through the transparent conductive film. Thereafter, in Step S7, solar battery elements are sealed with the EVA films, and in Step S8 a frame is mounted to thereby obtain a solar battery module.

The method for producing a solar battery of the present invention does not require the complicated soldering step, and has a less load on environment, since the interconnector is connected by bonding the transparent conductive film(s) to the solar battery element(s). Moreover, since the interconnector can be connected by thermal compression bonding when the solar battery is sealed with a sealant such as EVA, the production process can be simplified, and high temperature is not necessary upon soldering. Therefore, the occurrence of the warpage or cracks in the solar battery element, which has been conventionally a problem, can be inhibited.

### EXAMPLES

Hereinafter, the present invention will be specifically described with Examples and Comparative Examples, but the examples shall not be construed as limiting the scope of the present invention.

### Comparative Example 1

—Production of solar battery—
<Production of solar battery element>

Firstly, a solar battery element was produced as follow. A polycrystalline silicon substrate having a thickness of 200 μm and a size of 150 mm×150 mm was prepared, and a p-layer was formed within the substrate, and at the side of a light receiving surface of the substrate, and an n-layer was formed within the substrate and at the side of a non-light receiving surface of the substrate. Thereafter, over the n-layer, a silicon nitride film was formed by plasma CVD. Substantially, all over the non-light receiving surface (non-light receiving part) of the substrate, an aluminum paste was screen printed, dried at approximately 150° C., and baked at approximately 700° C. in the air.

Then, a silver paste was screen printed so as to form finger electrodes with intervals of 0.2 mm all over the light receiving surface of the substrate of the solar battery element, and a silver paste was screen printed on a land of the non-light receiving surface, dried and then baked at approximately 700° C., to thereby produce a solar battery element on which electrodes were formed.

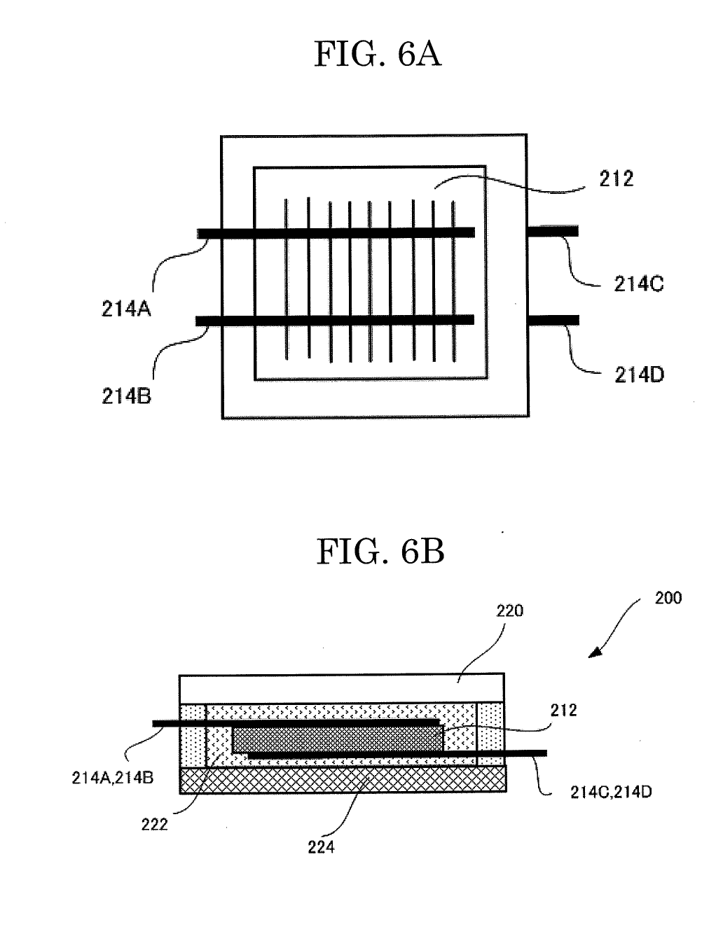

Next, the solar battery element on which electrodes were formed was immersed in flux, dried with hot air, and then immersed in a solder bath. Thereafter, the solar battery element was rinsed with purified water for 5 minutes, and then dried. The solar battery element was set in such a manner that a copper foil solder coated thereon was in contact with the silver electrodes present in a light receiving side and a non-light receiving side, blown with hot air at approximately 400° C. so as to melt adjacent solder metals into each other, and then cooled to thereby bond the copper foils 214A to 214D to a solar battery element 212 as shown in FIG. 6A. FIG. 6A shows a top view of the solar battery element 212 to which copper foils 214A to 214D are bonded.

Next, a glass substrate 220, an EVA film for sealing 222, a solar battery element 212, the other EVA film for sealing 222, and a back cover 224 were layered in this order, and then bonded them together by heat-melting, crosslinking, and curing the EVA films 222, to thereby produce a solar battery 200 shown in FIG. 6B. FIG. 6B shows a cross-sectional view of the solar battery 200.

### Production Method 1

### —Production of Transparent Conductive Film 101—

A transparent conductive film 101 was produced in accordance with Example 1 of JP-A No. 2004-221564 as described below.

Firstly, an emulsion which contained 7.5 g of gelatin with respect to 60 g of Ag in an aqueous medium, and contained silver bromide-iodide particles each having an average sphere-equivalent diameter of 0.05 μm (I=2% by mol), was prepared. In the emulsion K₃Rh₂Br₉ and K₂IrCl₆ were added so that the concentration of K₃Rh₂Br₉ and K₂IrCl₆ became 10⁻⁷ (mole/mole silver), and the silver bromide particles were doped with Rh ions and Ir ions. To the emulsion, Na₂PdCl₄ was added, and the emulsion was subjected to sulfur sensitization using chloroauric acid and sodium thiosulfate, and then was applied together with a gelatin hardening agent to a polyethylene terephthalate (PET) film substrate having a thickness of 50 μm so that a coated silver amount became 1 g/m². As the PET film substrate, the PET which had been previously subjected to a hydrophilic treatment was used. The coated silver film was dried and exposed to light using a UV lamp through a lattice-shaped photomask (specifically, a photomask having a lattice-shaped space with line/space=195 μm/5 μm and with a pitch of 200 μm) capable of forming a developed silver image with line/space=5 μm/195 μm on the dried coated silver film, and then developed at 25° C. for 45 seconds using the following developing solution, further treated using a fixing solution (SUPER FUJIFIX, manufactured by FUJIFILM Corporation), and rinsed with purified water.

### Composition of Developing Solution

The following compounds are contained per liter of the developing, solution.

| | |
|---|---|
| Hydroquinone | 0.037 mol/L |
| N-methylaminophenol | 0.016 mol/L |
| Sodium metaborate | 0.140 mol/L |
| Sodium hydroxide | 0.360 mol/L |
| Sodium bromide | 0.031 mol/L |
| Potassium metabisulfite | 0.187 mol/L |

Further, electroless copper plating was performed at 45° C. using a plating solution, which was an electroless Cu-plating solution having a pH vale of 12.5, and containing 0.06 mol/L of copper sulfate, 0.22 mol/L of formalin, 0.12 mol/L of triethanolamine, 100 ppm of polyethylene glycol, 50 ppm of yellow prussiate of potash and 20 ppm of α,α′-bipyridine, followed by oxidizing with an aqueous solution containing 10 ppm of Fe(III) ion, to thereby obtain transparent conductive film 101.

The obtained transparent conductive film was a lattice-shaped metal mesh formed on the PET substrate.

The surface resistance of the transparent conductive film on whose surface the metal mesh was formed was 1.1 Ω/sq as measured by Loresta-GP MCP-T600 manufactured by Mitsubishi Chemical Corporation. The transmittance of the film was 95% as measured by UV-3150 manufactured by SHIMADZU CORPORATION.

### Production Example 2

### —Production of Transparent Conductive Film 102—

As a mesh formed by printing a silver paste, a metal mesh was formed on a PET film substrate having a thickness of 50 μm in accordance with the method described in Example 1 of JP-A No. 2006-24485. A screen printing mesh with line/space=195 μm/5 μm and with a pitch of 200 μm was used for forming the metal mesh, to thereby produce a transparent conductive film 102. The obtained transparent conductive film 102 was a lattice-shaped metal mesh formed on the PET film substrate. The surface resistance of the transparent conductive film on whose surface the metal mesh was formed was 1.3 Ω/sq, and the transmittance of the film was 94% as measured in the same manner as in Production Example 1.

### Production Example 3

### —Production of Transparent Conductive Film 103—

As a metal mesh using a photography method, a metal mesh was formed on a PET film substrate having a thickness of 50 μm in accordance with the method for producing a metal mesh described in Example 3 of JP-A No. 2003-46293. A photomask with line/space=195 μm/5 μm and with a pitch of 200 μm was used for forming the metal mesh, to thereby produce a transparent conductive film 103. The obtained transparent conductive film 103 was a lattice-shaped metal mesh formed on the PET film substrate. The surface resistance of the transparent conductive film on whose surface the metal mesh was formed was 1.1 Ω/sq, and the transmittance of the film was 95%.

### Production Example 4

### —Production of Transparent Conductive Film 104—

A dispersion solution for a single wall carbon nanotube was prepared in accordance with Example 1 of Japanese Patent (JP-B) No. 3903159. A single wall carbon nanotube, which was synthesized based on Chemical Physics Letters, 323(2000) P580-585, and a polyoxyethylene-polyoxypropylene copolymer as a dispersing agent were added to a mixture of isopropyl alcohol and water in a ratio of 3:1 as a solvent. The amount of the carbon nanotube was 0.003% by mass and the amount of the dispersing agent was 0.05% by mass. The dispersion solution was applied to a surface of the PET film substrate having a thickness of 50 μm. After the dispersion solution was dried to form a film, an urethane acrylate solution in which the urethane acrylate was diluted with methyl isobutyl ketone to be a 1/600 fold in the concentration thereof was applied to the film, and dried, to thereby obtain a transparent conductive film 104. The transparent conductive film 104 was a transparent conductive film in which a conductive layer containing the carbon nanotube and the binder was formed on the PET substrate. The surface resistance of the transparent conductive film on whose surface the conductive layer containing the carbon nanotube was formed was 150 Ω/sq, and the transmittance of the film was 85%.

### Production Example 5

### —Production of Transparent Conductive Film 105—

### <Preparation of Metal Nanowire Dispersion>

The following loading solutions A, G, and H were prepared in advance.

[Loading solution A]

In 150 mL of purified water, 1.53 g of silver nitrate powder was dissolved. Thereafter, 1 N ammonia water was added thereto until the mixed solution became transparent. Then, purified water was further added so that the total amount of the solution became 300 mL.

[Loading solution G]

In 280 mL of purified water, 1.0 g of glucose powder was dissolved to thereby prepare a loading solution G.

[Loading solution H]

In 275 mL of purified water, 5.0 g of hexadecyl trimethyl ammonium bromide (HTAB) powder was dissolved to thereby prepare a loading solution H.

Next, a silver nanowire aqueous dispersion solution was prepared as follows.

Into a three-necked flask, 410 mL of purified water, 82.5 mL of the loading solution H, and 206 mL of the loading solution G were added by a funnel while stirring at 20° C. (first step). To this solution, 206 mL of the loading solution A was added at the flow rate of 2.0 mL/min., and stirring revolution of 800 rpm (second step). Ten minutes after the addition of the loading solution A, 82.5 mL of the loading solution H was added thereto. Thereafter, the mixed solution was heated up to 75° C. in terms of the inner temperature thereof at the heating rate of 3° C./min. Thereafter, the stirring revolution was dropped to 200 rpm and the mixed solution was heated for 5 hours while stirring.

After cooling the obtained aqueous dispersion, an ultrafiltration module SIP1013 (manufactured by Asahi Kasei Corporation, molecular cutoff: 6,000), a magnet pump, and a stainless steel cup were connected to each other with silicon tubes so as to form an ultrafiltration device.

The silver nanowire dispersion solution (aqueous solution) was loaded in the stainless steel cup, and then the pump was operated so as to carry out ultrafiltration. At the time when the amount of the filtrate from the module became 50 mL, 950 mL of distilled water was added to the stainless steel cup so as to carry out washing. The washing process was repeated until the conductivity became 50 μS/cm or less, followed by concentrating, to thereby finally obtain a silver nanowire aqueous dispersion solution.

The obtained silver nanoparticle is wire-shaped, and has an average minor axis diameter of 18 nm, and an average length of 38 μm.

To the obtained silver nanowire aqueous dispersion solution, a small amount of carboxy cellulose was added, and applied to a PET film substrate having a thickness of 50 μm, to thereby obtain a transparent conductive film 105. The transparent conductive film 105 was a transparent conductive film, in which a conductive layer containing the silver nanowire and the binder (carboxy cellulose) was formed on the PET film substrate. The surface resistance of the transparent conductive film on whose surface the conductive layer containing the silver nanowire was formed was 8 Ω/sq, and the transmittance of the film was 93%.

### Example 1

### —Production of Solar Battery—

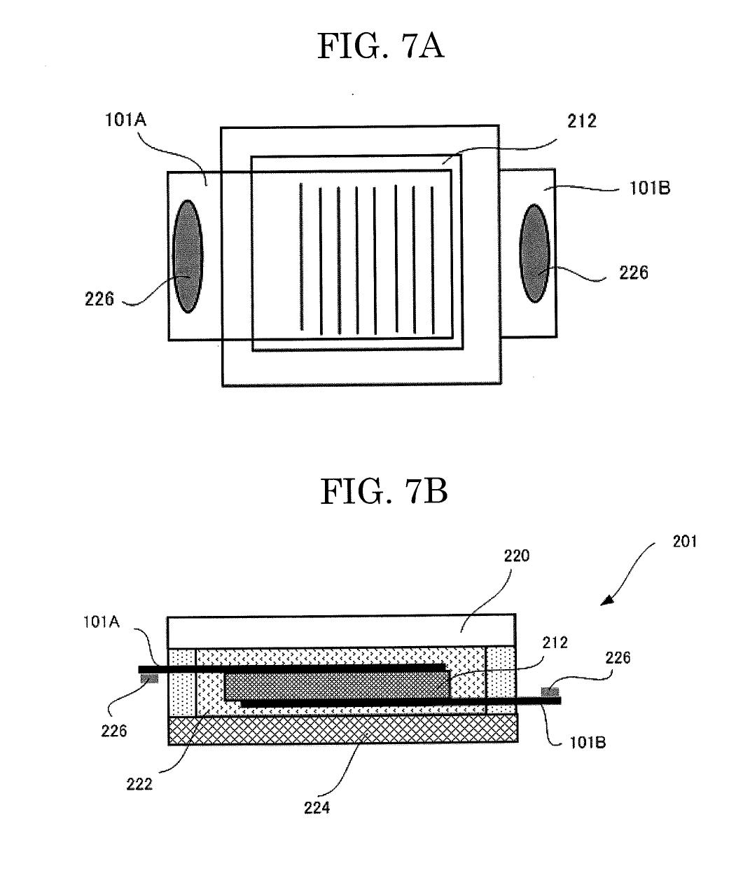

A solar battery element 212 on which electrodes were formed was produced in the same manner as in Comparative Example 1. The light receiving surface and non-light receiving surface of the solar battery element 212 were placed so as to bond respectively to the conductive layers of the transparent conductive films 101A and 101B, each of which was cut out in a size of 140 cm×170 cm (FIG. 7A). FIG. 7A shows a top view of the solar battery element 212.

Next, a glass substrate 220, an EVA film for sealing 222, a solar battery element (two transparent conductive films 101A and 101B bonded to the solar battery element 212), another EVA film for sealing 222, and a back cover 224 were layered in this order, and then bonded together by heat-melting, crosslinking and curing the EVA films 222, to thereby produce a solar battery 201 shown in FIG. 7B. FIG. 7B shows a cross-sectional view of the solar battery 201.

Further, a silver paste 226 was applied onto edges of respective transparent conductive films 101A and 101B so as to take out electric current.

Furthermore, solar batteries 202 to 205 were produced in the same manner as described above, respectively by the use of the transparent conductive films 102 to 105 produced in Production Examples 2 to 5.

### Comparative Example 2

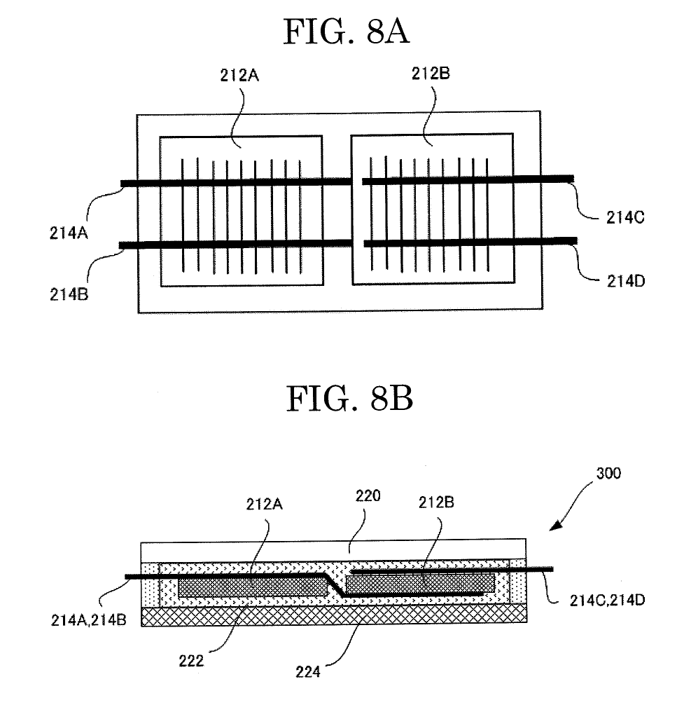

In the same manner as in Comparative Example 1, two solar battery elements were connected in series. Here, the solar battery elements were connected in such a manner that a copper foil connected to an electrode of a light receiving surface of one solar battery element 212A was connected to an electrode of a non-light receiving surface of the other solar battery element 212B (FIG. 8A). Then, a solar battery 300 shown in FIG. 8B was produced. FIG. 8A is a top view of the solar battery element 212 and FIG. 8B is a cross-sectional view of the solar battery 300.

### Example 2

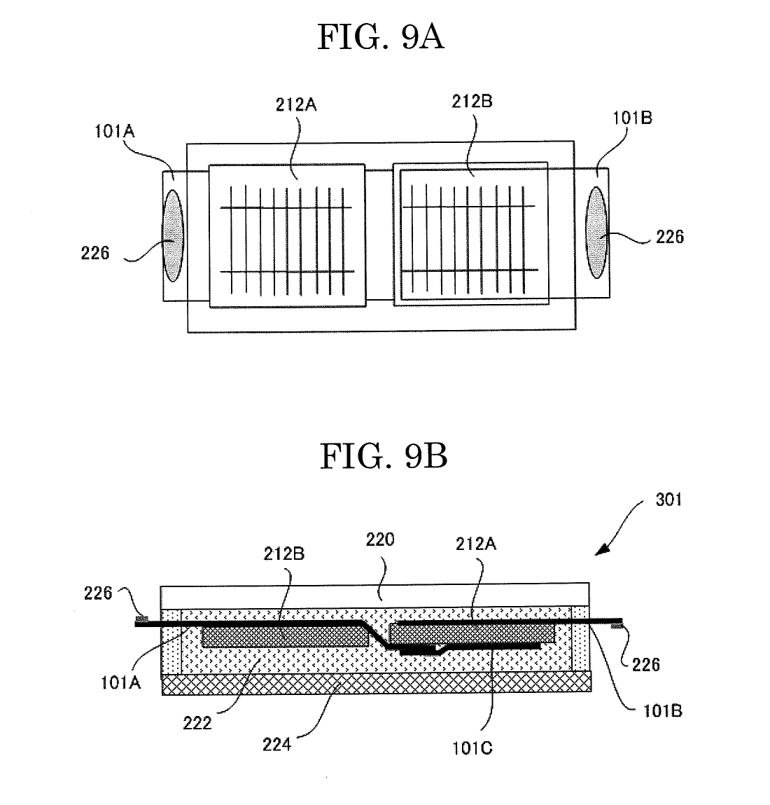

In the same manner as in Example 1, two solar battery elements were connected in series. Specifically, solar battery elements 212A and 212B on which electrodes were formed were respectively produced in the same manner as in Comparative Example 1. The light receiving surfaces of the solar battery elements 212A and 212B were placed so as to bond respectively to the conductive layers of the transparent conductive films 101A and 101B, each of which was cut out in a size of 140 cm×170 cm. Moreover, the surface of the conductive layer of the transparent conductive film 101A bonded to the light receiving surface of one solar battery element 212B was placed so that the surface of the conductive layer of the transparent conductive film 101C bonded to the non-light receiving surface of the other solar battery element 212A was bonded to the surface of the conductive layer of the transparent conductive film 101A, and then a glass substrate 220, an EVA film for sealing 222, solar battery elements 212A and 212B (three transparent conductive films 101A to 101C connecting two solar battery elements 212A and 212B), the other EVA film for sealing 222, and a back cover 224 were layered in this order, and then bonded together by heat-melting, crosslinking and curing the EVA films 222, to thereby produce a solar battery 301 shown in FIG. 9B. Further, a silver paste 226 was applied onto edges of respective transparent conductive films 101A and 101B so as to take out electric current. FIG. 9A shows a top view of the solar battery element 212 and FIG. 9B shows a cross-sectional view of the solar battery 301.

Furthermore, solar batteries 302 to 305 were produced in the same manner as described above, respectively by the use of the transparent conductive films 102 to 105 produced in Production Examples 2 to 5.

The following performance evaluations of the obtained solar batteries were performed to evaluate reliability. The results are shown in Table 1.

### <Performance Evaluation of Solar Battery>

The performance of the produced solar battery was measured before and after 10 cycles of temperature and humidity cycling test A-2 in accordance with JIS C 8917 were performed. Twenty of each of solar batteries 302 to 305 were produced and evaluated in the same manner.

The performance of the solar battery before and after the cycling test was evaluated by irradiating with light under the conditions of AM 1.5 and 100 mW/cm² and measuring the conversion efficiency using a solar simulator. Then, the average of measurement results of 20 solar batteries was calculated and evaluated.

TABLE 1

| | Conversion efficiency (%) | | |
|---|---|---|---|
| Sample | Before cycling test | After cycling test | |
| of solar | (Average of 20 solar | (Average of 20 | |
| battery | batteries) | solar batteries) | Remarks |
| 200 | 14 | 10 | Comparative Example |
| 201 | 16 | 15 | Present invention |
| 202 | 14 | 13 | Present invention |
| 203 | 15 | 13 | Present invention |
| 204 | 14 | 12 | Present invention |
| 205 | 16 | 15 | Present invention |
| 300 | 13 | 9 | Comparative Example |
| 301 | 15 | 13 | Present invention |
| 302 | 14 | 13 | Present invention |
| 303 | 14 | 13 | Present invention |
| 304 | 14 | 12 | Present invention |
| 305 | 15 | 14 | Present invention |

From the results of Table 1, it was found that the solar battery of the present invention using the transparent conductive film as an interconnector could obtain high conversion efficiency, that the performance of the solar battery of the present invention was less changed between before and after the temperature and humidity cycling test was performed, and that the solar battery of the present invention had high reliability. Note that, the difference in the conversion efficiency effect between before and after the temperature and humidity cycling test is 1% to 5% in number, but this difference is considered to be important as known in the art. When the ratio of the conversion efficiency is obtained, it is found that the difference in the conversion efficiency between before and after the temperature and humidity cycling test is large.

### Comparative Example 3

A solar battery module 400 was produced in the same manner as in Comparative Example 2, except that nine solar battery elements in a longitudinal direction and six solar battery elements in a lateral direction were connected in series.

### Example 3

A solar battery module 401 was produced in the same manner as in Example 2, except that nine solar battery elements in a longitudinal direction and six solar battery elements in a lateral direction were connected in series.

Solar batteries 402 to 405 were produced in the same manner as described above, respectively by the use of the transparent conductive films 102 to 105 produced in Production Examples 2 to 5.

The performance evaluations of the solar batteries obtained in Comparative Example 3 and Example 3 was performed in the same manner as described above so as to evaluate reliability. Here, the conversion efficiency was evaluated by averaging measurement result of three of each of solar batteries 400 to 405. The results are shown in Table 2.

TABLE 2

| | Conversion efficiency (%) | | |
|---|---|---|---|
| Sample | Before cycling test | After cycling test | |
| of solar | (Average of 3 solar | (Average of 3 | |
| battery | batteries) | solar batteries) | Remarks |
| 400 | 11 | 7 | Comparative Example |
| 401 | 13 | 12 | Present invention |
| 402 | 12 | 11 | Present invention |
| 403 | 12 | 10 | Present invention |
| 404 | 11 | 10 | Present invention |
| 405 | 12 | 11 | Present invention |

From the results of Table 2, it was found that when the solar battery of the present invention was produced by connecting nine solar battery elements in a longitudinal direction and six solar battery elements in a lateral direction in series, the performance of the solar battery of the present invention less changed between before and after the temperature and humidity cycling test was performed, and that the solar battery of the present invention had high reliability.

### INDUSTRIAL APPLICABILITY

The solar battery of the present invention has high conversion efficiency and reliability, and thus can be suitably used not only in residential application, and industrial application, but also in various fields such as an electronic calculator, watch, garden lighting, street light, and emergency power source. The method for producing a solar battery of the present invention does not require soldering, and can easily and efficiently produce a solar battery having a less load on environment, and having high conversion efficiency and reliability.

### REFERENCE SIGNS LIST

10, 12 solar battery element
14 transparent conductive film
30 glass substrate
32 back cover
34A, 34B EVA film
100 solar battery (the present invention)

1. A solar battery comprising:
a transparent conductive film; and
a solar battery element,
wherein the transparent conductive film is bonded to a surface of the solar battery element, and the transparent conductive film is electrically connected to the solar battery element, and
wherein the transparent conductive film comprises a film substrate and a conductive layer comprising a metal mesh, and two or more of the solar battery elements are electrically connected with each other in series or in parallel through the transparent conductive film.

2.-12. (canceled)

13. A method for producing a solar battery, comprising:
forming electrodes on both surfaces of a substrate so as to produce a solar battery element;
bonding a transparent conductive film to a plurality of the solar battery elements so as to interconnect the solar battery elements in series or in parallel; and
sealing the solar battery elements,
wherein the transparent conductive film comprises a film substrate and a conductive layer comprising conductive fibers.

14. The solar battery according to claim 1, wherein when a plurality of the solar battery elements are connected in series, the transparent conductive film bonded to a surface of the solar battery element is electrically connected to the transparent conductive film bonded to a surface of the another solar battery element.

15. A solar battery comprising:
a transparent conductive film; and
a solar battery element,
wherein the transparent conductive film is bonded to a surface of the solar battery element, and the transparent conductive film is electrically connected to the solar battery element, and
wherein the transparent conductive film comprises a film substrate and a conductive layer comprising conductive fibers, and two or more of the solar battery elements are electrically connected with each other in series or in parallel through the transparent conductive film.

16. The solar battery according to claim 15, wherein when a plurality of the solar battery elements are connected in series, the transparent conductive film bonded to a surface of the solar battery element is electrically connected to the transparent conductive film bonded to a surface of the another solar battery element.

17. The solar battery according to claim 15, wherein the conductive fibers are any one of carbon nanotubes and metal nanowires.

18. The solar battery according to claim 17, wherein the metal nanowire is a silver nanowire.

19. An interconnection method comprising:
connecting two or more transparent conductive films, each of which is bonded to a surface of a solar battery element, so as to electrically connect two or more of the solar battery elements with each other in series or in parallel,
wherein the transparent conductive film comprises a film substrate and a conductive layer comprising conductive fibers.
